(19) United States
(12) Patent Application Publication
(10) Pub. No.: US 2018/0130804 A1
(43) Pub. Date: May 10, 2018

(54) Vertical Thyristor Cell and Memory Array with Silicon Germanium Base Regions

(71) Applicant: Kilopass Technology, Inc., San Jose, CA (US)

(72) Inventors: Harry Luan, Saratoga, CA (US); Valery Axelrad, Woodside, CA (US); Charlie Cheng, Los Altos, CA (US)

(21) Appl. No.: 15/807,536

(22) Filed: Nov. 8, 2017

Related U.S. Application Data
(60) Provisional application No. 62/419,377, filed on Nov. 8, 2016.

(51) Int. Cl. H01L 27/105; H01L 27/08; H01L 29/06; H01L 29/165; H01L 29/74; H01L 29/66; H01L 21/8229; H01L 21/762; H01L 21/02; H01L 21/265

(52) U.S. Cl. CPC H01L 27/1052; H01L 27/0817; H01L 29/0649; H01L 29/165; H01L 21/26513; H01L 29/66378; H01L 21/8229; H01L 21/76224; H01L 21/02532; H01L 29/742

(57) ABSTRACT

Memory arrays of vertical thyristor memory cells with SiGe base layers are described. The composition of the SiGe can be constant or varied depending upon the desired characteristics of the memory cells. The memory cells allow a compact structure with desirable low voltage operations.

### CROSS-REFERENCE TO RELATED APPLICATIONS

This patent application claims priority to U.S. Provisional Patent Application No. 62/419,377, filed Nov. 8, 2016 and entitled, “Vertical Thyristor Cell and Memory Array with Silicon Germanium Base Regions.”

### BACKGROUND OF THE INVENTION

This invention relates to semiconductor devices for information storage. In particular, the devices can be used as volatile memories such as static (SRAMs) and dynamic random access memories (DRAMs).

The 1-transistor/1-capacitor (1T1C) cell has been the only memory cell used in DRAM devices for the last 30 years. Bit density has quadrupled every 3 years by lithographical scaling and ever increasing process complexity, sometimes stated as “Moore's Law.” However, maintaining the capacitance value and low transistor leakage has become a major problem for further scaling.

Alternative DRAM cells have been proposed to overcome the scaling challenges of conventional 1T1C DRAM technology. These include: Floating body DRAM (FBDRAM), a single MOSFET built on either a silicon-on-insulator (SOI) (Okhonin, Int. SOI Conf., 2001) or in triple-well with a buried n-implant (Ranica, VLSI Technology, 2004). But the technology has yet to solve its data retention issues, particularly at scaled dimensions.

Various cell designs have been proposed based on the negative differential resistance (NDR) behavior of a PNPN thyristor. An active or passive gate is mostly used in these designs for trade-offs among switching speed, retention leakage, or operation voltage. The thin capacitively coupled thyristor (TCCT), as disclosed by U.S. Pat. No. 6,462,359, is a lateral PNPN thyristor constructed on a SOI substrate and has a coupling gate for increased switching speed. Due to its lateral 2D design and the need of a gate, the cell size can be much larger than the 1T1C cell which is about 6˜8F² where F is the minimum feature size of the particular process technology.

Recently, Liang in U.S. Pat. No. 9,013,918 disclosed a PNPN thyristor cell that is constructed on top of silicon substrate and operated in forward and reverse breakdown region for writing data into the cell. Due to the use of epitaxial or CVD semiconductor layers at the backend of the standard CMOS process, add-on thermal cycles and etch steps could potentially degrade performance and yield of devices already built in the substrate. In addition, PNPN devices operated in the breakdown regime may pose challenges in process control and also power consumption.

Recent applications, such as U.S. Pat. No. 9,564,199, which issued Feb. 7, 2017, and assigned to the present assignee, and related patents teach the use of bulk vertical thyristors arranged in cross-point arrays for high density RAM applications. They are used for, and incorporated by, reference here.

Problems still remain, nonetheless. As the isolation trenches in thyristor memories become narrower, it becomes more difficult to include assist gates inside these trenches and gate resistance poses a challenge in signal delays. Without assist gates, switch voltages for write and read operations can be higher than available supply voltages as the technology further scales downward. There is a need, therefore, for a compact thyristor cell and array design that is not only small and reliable but also can be operated at low voltage levels.

### BRIEF SUMMARY OF THE INVENTION

The present invention provides for an integrated circuit memory array having a cross-point array of vertical thyristor memory cells interconnected by pluralities of first and second parallel conducting lines, which are perpendicular to each other. Each vertical thyristor memory cell is connected to a pair of first and second parallel conducting lines at an intersection of the first and second parallel conducting lines. The vertical thyristor memory cell comprises a top layer of a first conductivity type; a first intermediate layer of a second conductivity type, the first intermediate layer below the top layer; a second intermediate layer of the first conductivity type, the second intermediate layer below the first intermediate layer, at least one of the intermediate layers comprising a silicon-germanium alloy; and a bottom layer of second conductivity type, the bottom layer below the second intermediate layer; wherein the top, first intermediate, second intermediate and bottom layers are stacked vertically in a semiconductor substrate. The concentration of germanium in the at least one of the intermediate layers may be constant or may vary, depending upon the desired performance of the cell.

The present invention also provides for a method of manufacturing vertical thyristor memory cells in an integrated circuit array. The method comprises: defining a plurality of first isolation trenches in a surface of a silicon substrate of first conductivity type, the first isolation trenches lines in a first direction; filling the plurality of first isolation trenches with an insulating material; defining a plurality of second isolation trenches over the surface of the silicon substrate in a second direction perpendicular to the first direction; filling the plurality of second isolation trenches with an insulating material; etching apertures in the surface of the silicon substrate, each aperture between a pair of first isolation trenches and a pair of second isolation trenches to create a bottom at a predetermined depth in the silicon substrate; implanting dopants of second conductivity type to create a bottom layer of the second conductivity type at the bottom of the aperture; growing a SiGe layer of first conductivity type in the aperture over the bottom layer of second conductivity; and growing a SiGe layer of second conductivity type in the aperture over the SiGe layer of first conductivity type; growing a top layer of a first conductivity type in the aperture over the SiGe layer of second conductivity type. The bottom layer of second conductivity type, the SiGe layer of first conductivity type, the SiGe layer of second conductivity type and the top layer of first conductivity type forms a memory cell thyristor stacked vertically in the silicon substrate surface.

Other objects, features, and advantages of the present invention will become apparent upon consideration of the following detailed description and the accompanying drawings, in which like reference designations represent like features throughout the figures.

### BRIEF DESCRIPTION OF THE DRAWINGS

FIGS. 1A and 1B are perpendicular cross-sectional views of vertical thyristor memory cells which have SiGe alloy base layers according to one embodiment of the present invention.

FIGS. 2A to 2M illustrates manufacturing process steps to make the vertical thyristor memory cells shown in FIGS. 1A and 1B, according to an embodiment of the present invention.

FIGS. 3A and 3B show perpendicular cross-sectional views of vertical thyristor memory cells which have an intrinsic SiGe alloy layer between two SiGe alloy layers of opposite conductivity types, according to another embodiment of the present invention. The intrinsic SiGe layer is inserted to reduce the band-to-band tunneling leakage.

FIGS. 4A and 4B show perpendicular cross-sectional views of vertical thyristor memory cells which have a structure similar to that of FIGS. 1A and 1B, except that the N+ bottom layer is connected to the bottom layers of neighboring memory cells by a metal bridge on top of a N+ doped silicon linking region traversing an insulating trench to form a conducting line, according to another embodiment of the present invention.

FIGS. 5A and 5B show perpendicular cross-sectional views of vertical thyristor memory cells which have a structure similar to that of FIGS. 4A and 4B, except an intrinsic SiGe layer inserted between two SiGe alloy layers of opposite conductivity types, according to still another embodiment of the present invention.

FIGS. 6A and 6B show cross-sectional views of vertical thyristor memory cells similar to those of FIGS. 1A and 1B, which have gate electrodes for PMOS and NMOS write assist transistors respectively.

### DETAILED DESCRIPTION OF THE INVENTION

An integrated circuit memory array according to the present invention has a cross-point array of vertical thyristor memory cells at the surface of a semiconductor substrate. The memory cells are interconnected by first and second parallel conducting lines which are perpendicular to each other. Each vertical thyristor memory cell is connected to a pair of first and second parallel conducting lines at an intersection of the conducting lines. Each vertical thyristor memory cell is also isolated from other vertical thyristor memory cells in the array by first and second parallel isolation trenches which are perpendicular to each other. Details of the vertical thyristor memory cell and the memory array are described below.

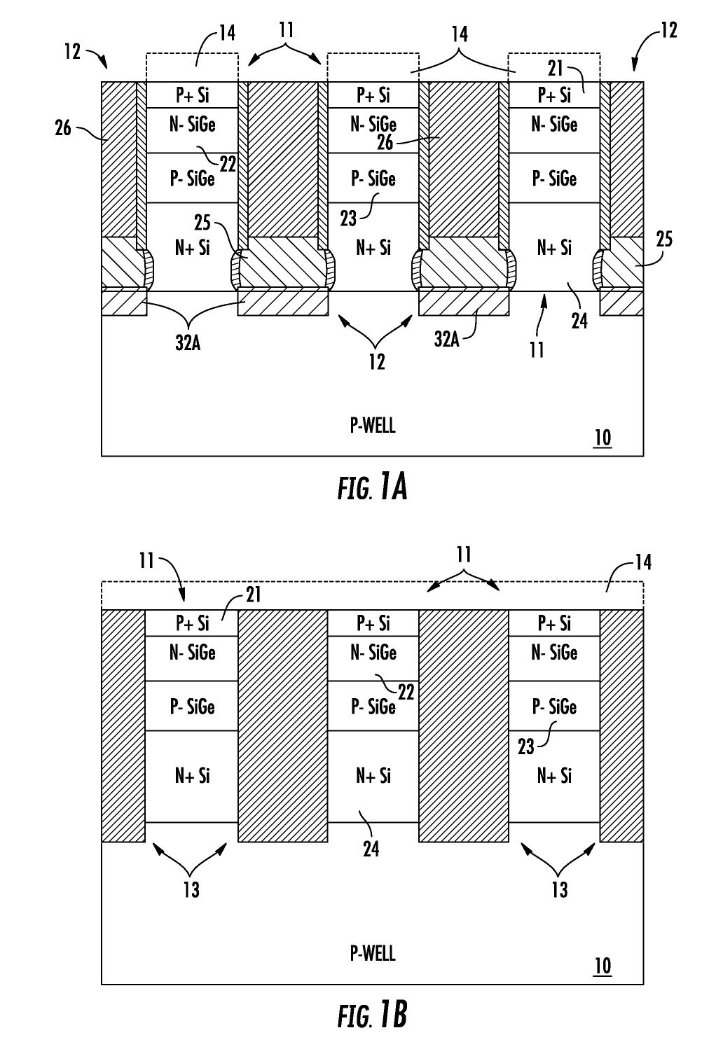

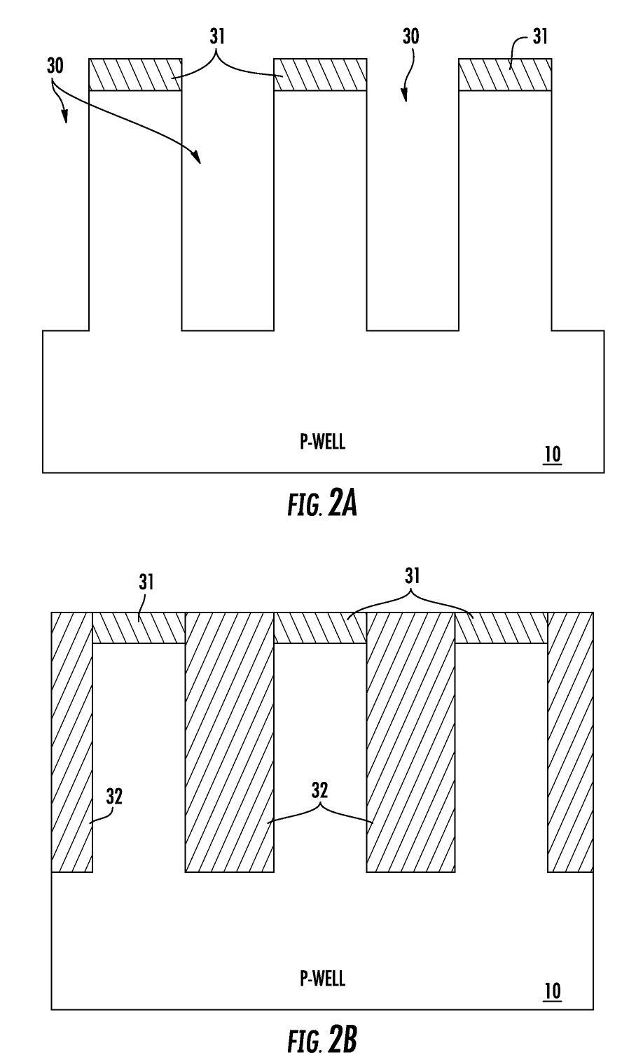

FIGS. 1A and 1B are perpendicular cross-sectional views of three vertical thyristor memory cells 11 in the array, according to one embodiment of the present invention. Formed in part of a semiconductor substrate, a P-well 10, the vertical thyristor memory cells 11 are separated by two sets of parallel isolation trenches 12 and 13 which run perpendicularly to each other. Each vertical thyristor memory cell has a top layer of P+ silicon 21, a first intermediate layer of N− SiGe alloy 22, a second intermediate layer of P− SiGe alloy 23 and a bottom layer of N+ silicon 24. The P+ top layer 21 forms the anode and the N+ bottom layer 24 forms the cathode of each thyristor of a memory cell 11.

Two sets of parallel conducting lines which also run in perpendicular directions interconnect the memory cells in the memory array. One set of parallel conducting lines 14 runs over the vertical thyristor memory cells and are connected to the anodes, the top layer 21, of the cells. These lines 14 shown by dotted lines run perpendicularly to the drawing of FIGS. 1A and 1n the drawing plane of FIG. 1B. The conducting lines 14 can be formed by a metal, such as copper, layer or metal silicide layer.

The second set of conducting lines is formed partially by the bottom layers 24, the cathodes, of the vertical thyristor memory cells. These lines run in the plane of FIG. 1B and perpendicularly to the drawing of FIG. 1A. In the cross-point array either set of conducting lines can be termed the word lines and the other set of conducting lines can be termed the bit lines of the array. Not shown in the drawings are a set of metal lines, such as copper, which run parallel to and over the conducting lines formed by the bottom layers 24. These metal lines are periodically connected to the bottom layer conducting lines by metal plugs to improve the conductivity of the bottom layer conducting lines. More details of the bottom (cathode) layers 24 are described below.

The intermediate layers 22 and 23 form the base layers of the vertical thyristor memory cells 11. Unlike previous thyristor memory cells with silicon regions of alternating P and N conductivities, the base layers 22 and 23 are formed by SiGe (Silicon-Germanium) alloys. The SiGe base layers 22, 23 permit the thyristor memory cell to turn on at lower voltages than a similar structure with silicon base regions. The N and P-type SiGe base regions 22, 23 may have a constant Germanium composition of 2-30% mole fraction. Alternatively, the Germanium composition in the alloy of the two base regions may vary. The Ge fraction may be linearly graded such that Ge mole fraction is low near the middle N-base/P-base junction and higher towards both anode and cathode junctions. The result is that the bandgap is large at the middle junction and therefore band-to-band tunneling is reduced during the switch-on operation. Still another variation in the SiGe composition reverses the linear grading so the Ge mole fraction near the middle junction is high and the Ge mole fraction near both the anode and cathode junctions is low. Band-to-band tunneling leakage is reduced during the turn-off operation.

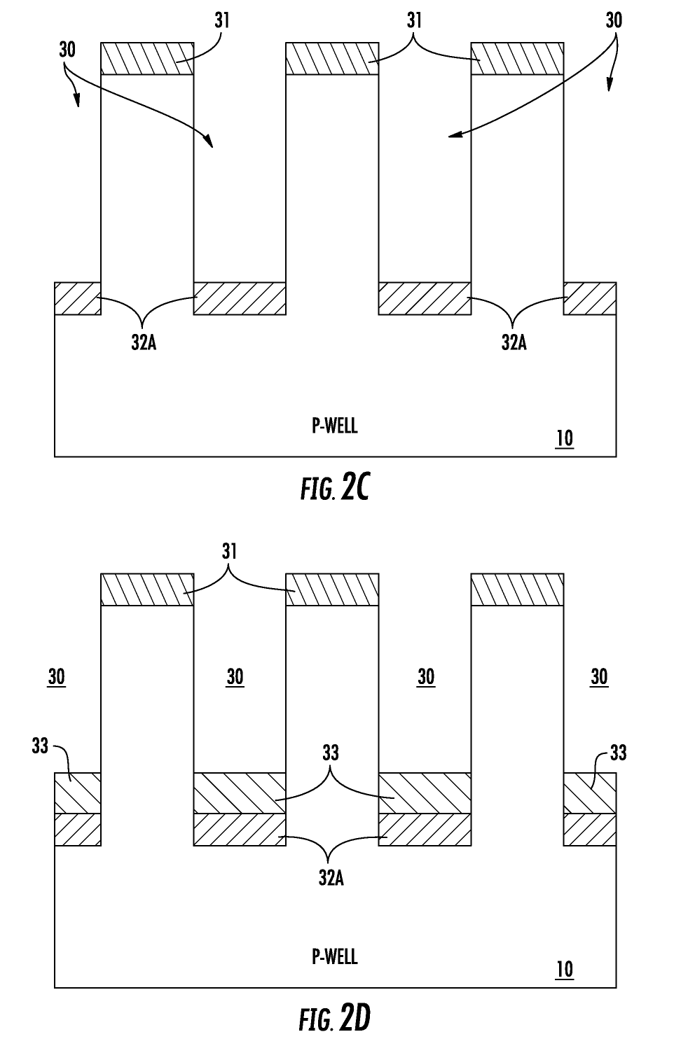

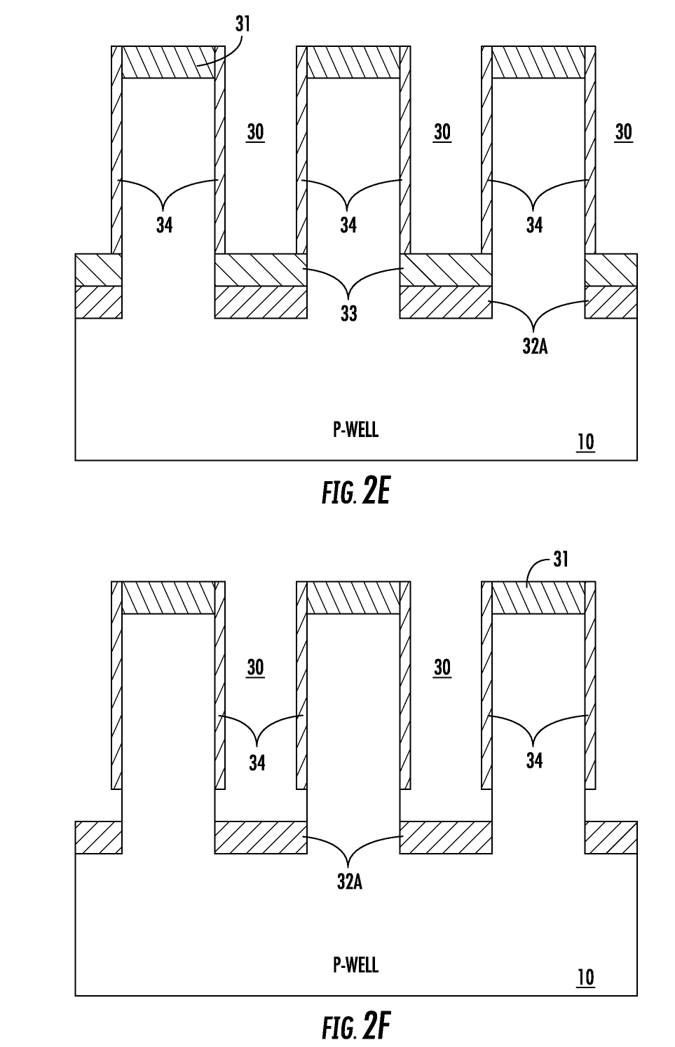

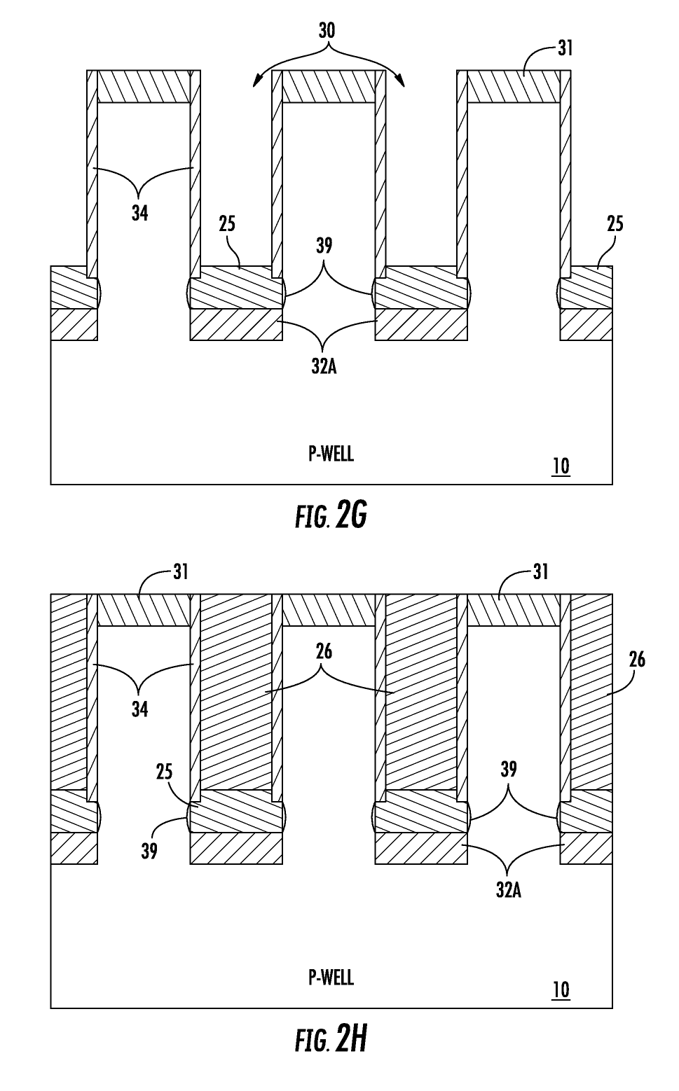

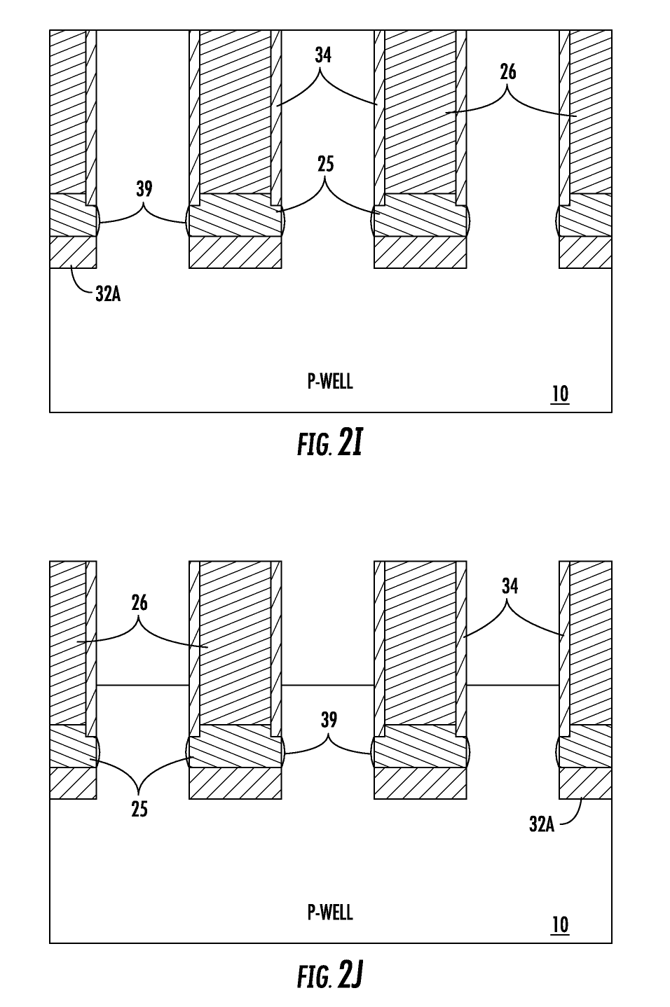

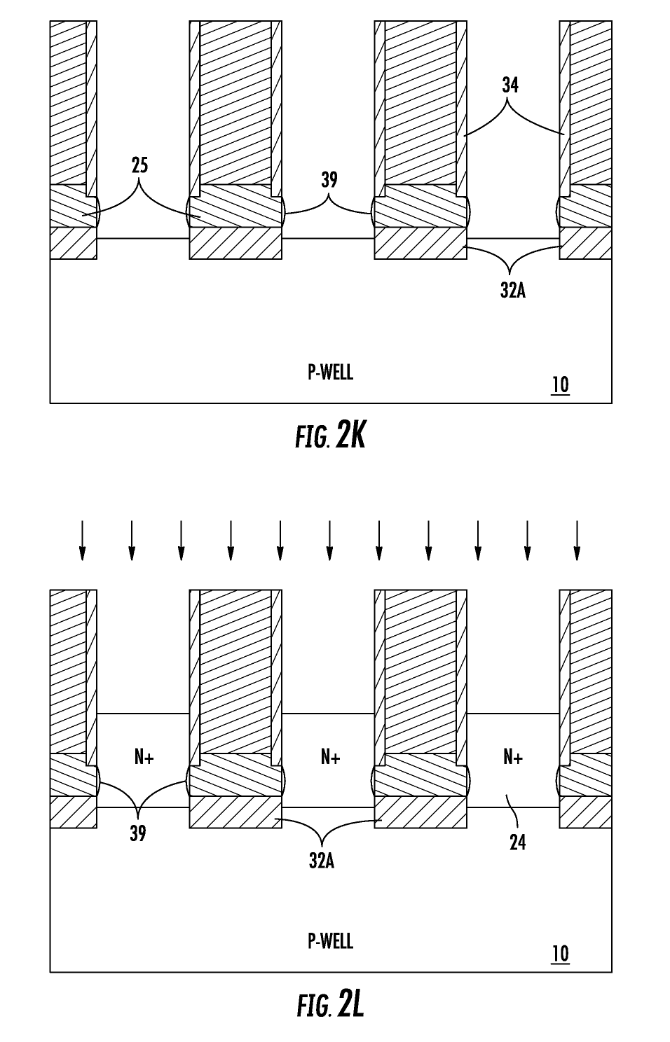

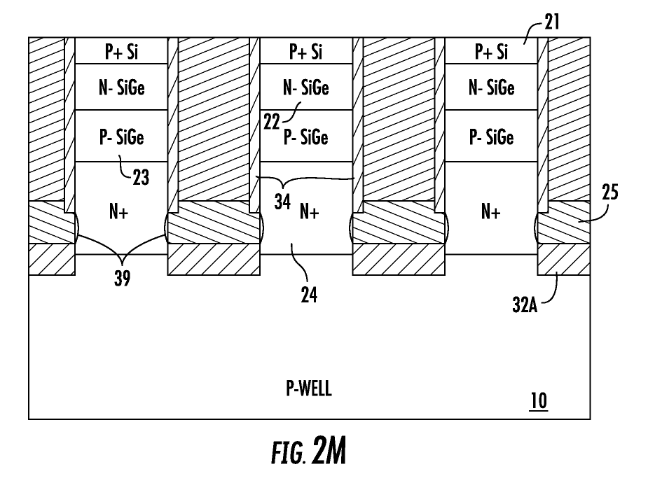

FIGS. 2A to 2M show different steps of an exemplary process flow to make the vertical thyristor memory cells and memory array illustrated by FIGS. 1A and 1B using operational steps well-known in the semiconductor process technology. Hence not all of the details have been described but should be readily apparent to a person familiar with semiconductor processing. It should be noted that the same references numerals are used in one drawing for elements which are the same or substantially similar in another drawing to help the understanding of the reader.

The process starts with the first set trench definition step using a hard mask of a silicon nitride layer over a thin pad layer of silicon dioxide and followed by a RIE (Reactive Ion Etching) of a first set of parallel trenches in a P-well region of a semiconductor substrate. The first set of parallel trenches is then filled with silicon dioxide by, for example, a high-density plasma (HDP) enhanced chemical vapor deposition (CVD) process after a growth of a thin layer of oxide on the bottom and sides of the silicon trenches. The direction of the first set of parallel trenches is perpendicular to the first set of conducting lines 14 as shown in FIG. 1A. Following a chemical mechanical polishing step to remove any excess any trench oxide down to the pad oxide layer. Then another masking hard mask of a silicon nitride layer over a thin pad layer of silicon dioxide is defined for a second set of parallel trenches perpendicular to the first set of parallel trenches to create a checkerboard pattern. Then a silicon etch by an RIE operation is performed creating a set of holes 30 into the P-well at the locations of exposed silicon. This is shown in FIG. 2A in a cross-sectional view along the direction of the first set of parallel trenches. Only the hard mask of nitride layer 31 is shown; the underlying thin silicon oxide layer is not.

FIG. 2B shows the results of an insulation material 32 (such as silicon dioxide) deposition step by a HDP CVD step which fills the holes 30 and subsequent planarization by a CMP step. This is followed by an oxide etch back step by a selective RIE step, which removes most of the material 32 to leave a layer of oxide 32A at the bottom of the holes 30, as shown in FIG. 2C. A layer of sacrificial layer (carbon in this example) is deposited by CVD and etched back by a RIE step, leaving a sacrificial layer 33 on top of the oxide layer 32A at the bottom of the holes 30 as shown in FIG. 2D. This is followed by a conformal insulator (nitride) deposition and etch back to form nitride spacers 34 along the silicon sidewalls of the holes 30 as shown in FIG. 2E. Then the sacrificial layer 33 is removed, by an ashing operation step is performed with a wet or dry isotropic etch, such as a plasma-oxygen process, for example. FIG. 2F shows the results.

Then thin silicide layers 39 are created on the silicon exposed by the removal of the sacrificial layer. A refractory metal, such as titanium, cobalt, or nickel, is deposited on the surface of the semiconductor wafer and holes 30. A rapid-thermal anneal (RTP) is then performed to create a conductive metal silicide in the exposed P-well silicon below the nitride spacers 34 in the holes 30. The un-reacted metal is then removed by a wet etch. This is not shown in the drawings. This is followed by the deposition of a metal layer, such as W (tungsten), layer, which is followed by a selective RIE etch back step. The result is shown in FIG. 2G. The resulting metal plugs form the metal contact bridges 25 of FIGS. 1A and 1B with the thin silicide layer on the lateral surfaces of W metal bridges 25 allowing ohmic contacts between the W metal bridges and the cathode N+ layer of the thyristor cell to be created subsequently.

Returning to the particular point of the process flow, an insulating oxide layer 26 is then deposited by HDP CVD to fill the holes 30, as shown in FIG. 2H. This is followed by an oxide etch and a nitride strip operation to planarize the semiconductor surface, as illustrated by FIG. 2I. A silicon etch shown by FIG. 2J removes silicon where the vertical thyristor memory cells are to be located; the silicon is removed to a depth about 100 nm above the buried metal contact bridges 25. Following the silicon etch step of FIG. 2J, the exposed silicon areas are implanted with N-type dopants to form N+ regions at the bottom of the cells-to-be, as shown by FIG. 2L. Then a P− SiGe layer 23 is selectively grown, followed by the N− SiGe layer 22. These SiGe base regions are selectively and pseudomorphically grown by a replacement silicon approach which has the advantages of precise in-situ doping and thickness control. Hence the SiGe base layers 22, 23 may have a constant or varying composition as described above. Finally a P+ epitaxial silicon layer 21 is grown. The results are illustrated in FIG. 2M.

Rather than switching to silicon, the P+ top layer can be selectively grown as a P+ SiGe layer so that the resulting vertical thyristor memory cell structure has three SiGe layers, the two base layers 22 and 23, and the anode layer 21. [Harry, perhaps you can mention here any advantages of such a memory cell structure.]

FIG. 2K shows an alternative process step to that of FIG. 2J. In this step, the silicon etch removes the silicon about 20 nm below the metal contact bridges 25. An N+ epitaxial layer 21 is grown. Then the P− SiGe base layer 23, the N− SiGe base layer 22 and the P+ epitaxial silicon layer 21 are selectively grown, as previously described. The alternative process step of FIG. 2K lowers the possibility that a W metal bridge 25 is shorted to the P-well 10.

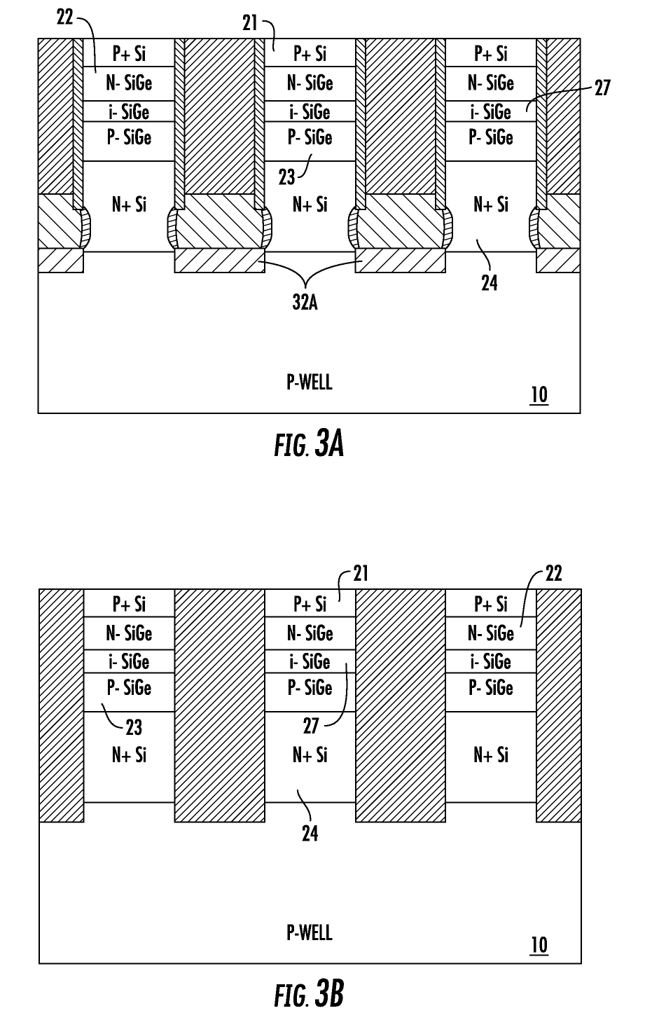

Different vertical thyristor memory cell structures can be provided according to other embodiments of the present invention. FIGS. 3A and 3B show perpendicular cross-sectional views of a vertical thyristor cell which has an intrinsic SiGe alloy layer 27 between two SiGe alloy layers 22, 23 of opposite conductivity types. The intrinsic SiGe layer 27 increases the depletion layer width under a reverse-biased middle junction so that so that band-to-band tunneling can be significantly reduced.

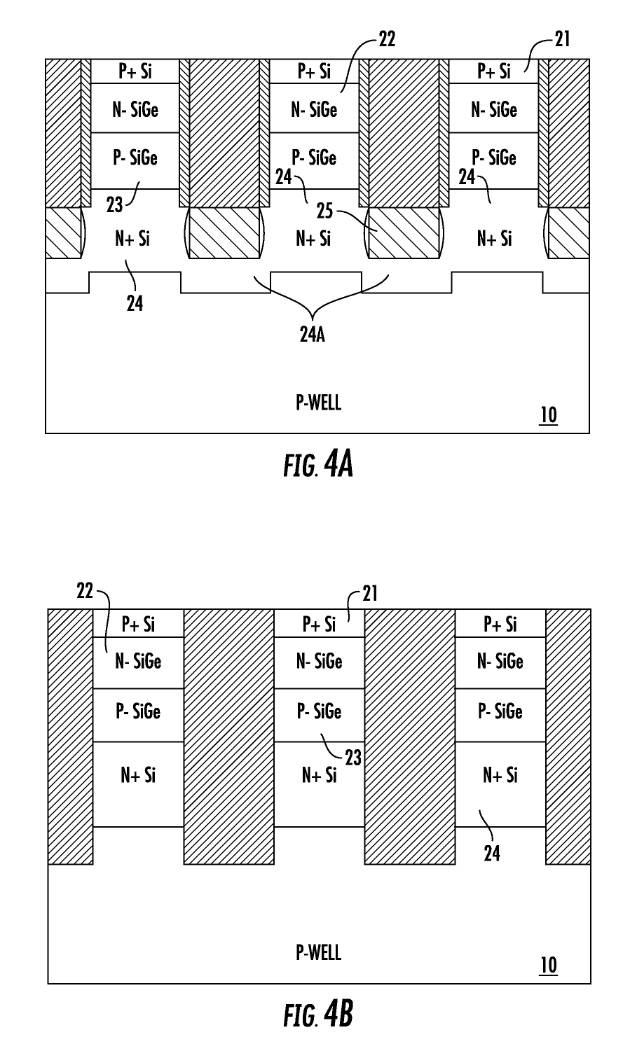

Another memory cell structure similar to that of FIGS. 1A and 1B, is illustrated in the perpendicular cross-sectional views of FIGS. 4A and 4B. In this cell structure that the N+ bottom layer, i.e., the thyristor cell cathode 24, is connected to the bottom layers of neighboring memory cells by a metal bridge 25 on top of a N+ doped silicon linking region 24A traversing an insulating trench to form a conducting line. The N+ layer 24A below the metal bridges 25 is formed by removing all of the oxide in the holes in the etch step of FIG. 2C. Then an N+ implant step is performed creating the N+ regions 24A at the bottom of the holes 30. This is followed by the deposition of the sacrificial carbon layer described with respect to FIG. 2D and the remaining process steps described earlier are followed. Like the alternative process related to FIG. 2K, the N+ regions 24A reduce the possibility that a metal bridge 25 is shorted to the P-well 10.

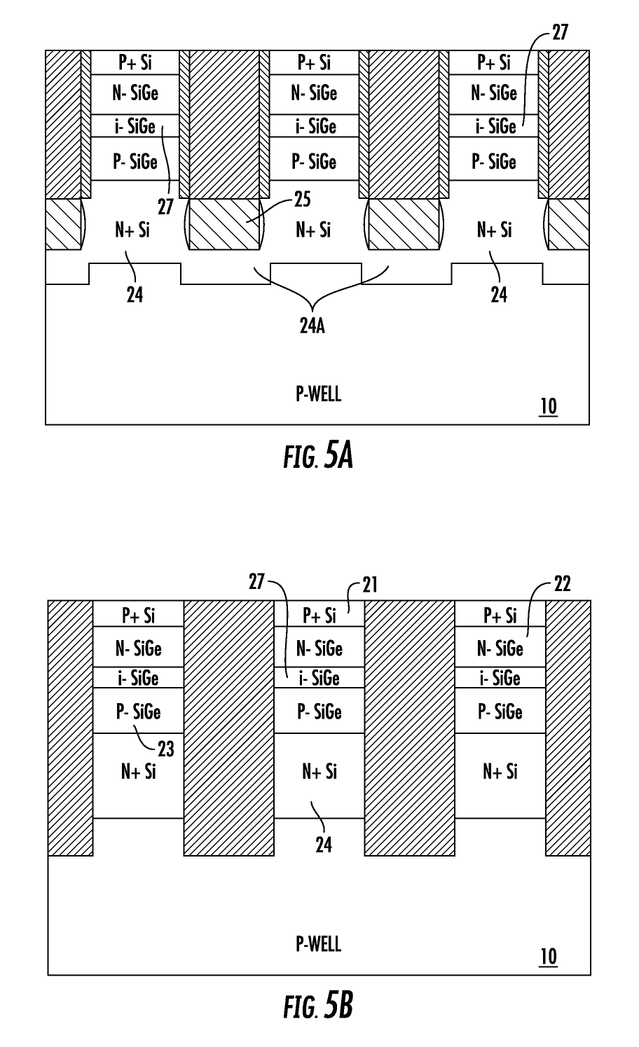

FIGS. 5A and 5B show a vertical thyristor memory cell which has a structure similar to that of FIGS. 4A and 4B, except an intrinsic SiGe layer 27 has been inserted between the two SiGe alloy layers 22, 23 of opposite conductivity types, according to still another embodiment of the present invention.

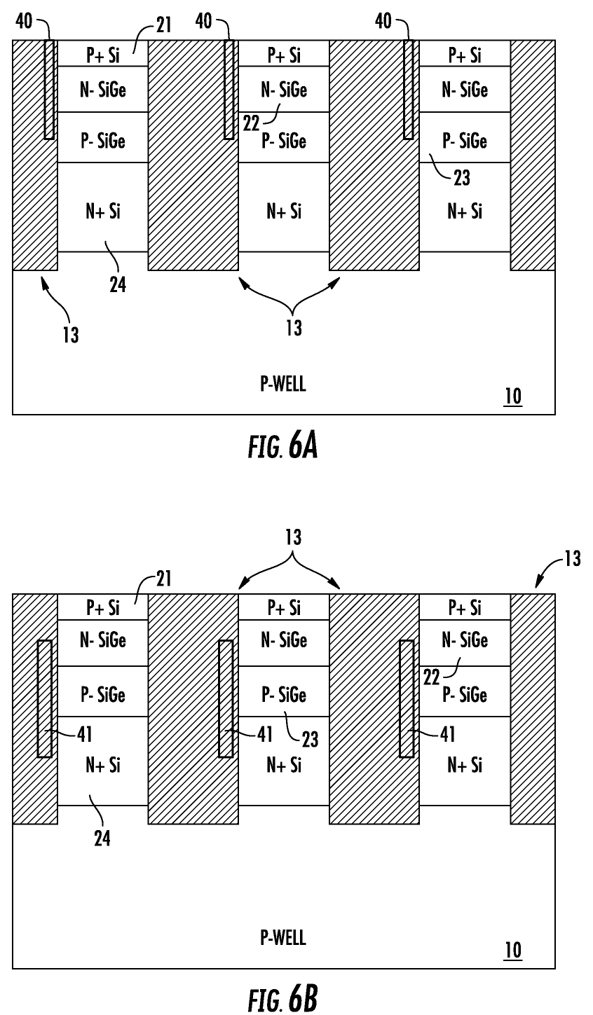

In another embodiment of the present invention MOSFET (Metal-Oxide-Semiconductor Field Effect Transistor) gate electrodes are added to the vertical thyristor memory cell to speed the operations of the cell. These gate electrodes are built into the isolation trenches 13 and/or 12. In FIG. 6A, gate electrodes 40 lie in the isolation trench 13 and are located over and span the N− base SiGe layer 22 to form a PMOS transistor with top P+ layer 21 and the P− SiGe base layer 23 acting as source/drain regions and the N− SiGe layer 22 as the body region. The gate electrodes 40 are separated from the body region by a thin gate oxide layer. In FIG. 6B, gate electrodes 41 lie in the isolation trench 13 and are located over and span the P− base SiGe layer 23 to form a NMOS transistor with the N− SiGe base layer 22 and the N+ cathode layer 24 acting as source/drain regions and the P− SiGe layer 23 as the body region. The gate electrodes 41 are separated from the body region by a thin insulating layer. These MOSFET structures can help in the write operations of the vertical thyristor memory cell by allowing the memory cell to turn on more quickly. The vertical thyristor memory cells may have the write assist gate electrodes for one write assist MOS transistor, PMOS transistor (formed by P+ layer 21, N− SiGe layer 22 and P− SiGe layer 23) or NMOS transistor (formed by N− SiGe layer 22, P− SiGe layer 23 and N+ layer 24), or both write assist MOS transistors. With two write assist MOS transistors, the gate electrodes are located in both isolation trenches 13 and 12 to avoid interfering with each other.

The gate electrodes for a particular isolation trench are formed after the isolation trench is etched and the trench gate oxide is formed. The trench is then partially filled with silicon dioxide to a depth above the N-cathode/P-base junction, i.e., the junction between the bottom N+ layer 24 and the P− SiGe base layer 23, in the case of the gate electrodes of FIG. 6A. A conformal conductive gate layer of, e.g. doped polycrystalline silicon is then formed. The gate layer is then anisotropically etched to form a sidewall gate completely covering the N-type base. Finally the trench is filled with silicon dioxide and then planarized, using well known technology. Of course, care must be taken so that the added manufacturing steps for gate electrodes do not interfere with the previously described steps for manufacturing the vertical thyristor memory cell.

The described vertical thyristor memory cells provide for a memory array in which the cells are compactly arranged and small. Even with shrinking integrated circuit geometries, operation of the cells is reliable at the lowering voltage levels.

This description of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications. This description will enable others skilled in the art to best utilize and practice the invention in various embodiments and with various modifications as are suited to a particular use. The scope of the invention is defined by the following claims.

The invention claimed is:

1. In an integrated circuit memory array having a cross-point array of vertical thyristor memory cells interconnected by pluralities of first and second parallel conducting lines, the first parallel conducing lines in a first direction and the second parallel conducting lines in a second direction perpendicular to the first direction, each vertical thyristor memory cell connected to a pair of first and second parallel conducting lines at an intersection of the first and second parallel conducting lines, the vertical thyristor memory cell comprising:
a top layer of a first conductivity type;
a first intermediate layer of a second conductivity type, the first intermediate layer below the top layer;
a second intermediate layer of the first conductivity type, the second intermediate layer below the first intermediate layer, at least one of the intermediate layers comprising a silicon-germanium alloy; and
a bottom layer of second conductivity type, the bottom layer below the second intermediate layer;
wherein the top, first intermediate, second intermediate and bottom layers are stacked vertically in a semiconductor substrate.

2. The vertical thyristor memory cell of claim 1 wherein the concentration of germanium in the at least one of the intermediate layers remains constant.

3. The vertical thyristor memory cell of claim 1 wherein the concentration of germanium in the at least one of the intermediate layers varies.

4. The vertical thyristor memory cell of claim 1 wherein both the first and second intermediate layers comprise silicon-germanium alloys.

5. The vertical thyristor memory cell of claim 4 wherein the concentration of germanium in the at least one of the intermediate layers remains constant.

6. The vertical thyristor memory cell of claim 5 wherein the concentration of germanium in both the intermediate layers remains constant.

7. The vertical thyristor memory cell of claim 4 wherein the concentration of germanium in the at least one of the intermediate layers varies.

8. The vertical thyristor memory cell of claim 7 wherein the concentration of germanium in both the intermediate layers varies.

9. The vertical thyristor memory cell of claim 8 wherein the concentration of germanium in each of the intermediate layers increases approaching the other intermediate layer.

10. The vertical thyristor memory cell array of claim 8 wherein the concentration of germanium in each of the intermediate layers decreases approaching the other intermediate layer.

11. The vertical thyristor memory cell array of claim 8 wherein the concentration of germanium in each of the intermediate layers varies in a range of 2-30% mole fraction.

12. The vertical thyristor memory cell of claim 1 further comprising a third intermediate layer between the first and second intermediate layers, the third intermediate layer comprises intrinsic silicon-germanium alloy.

13. The vertical thyristor memory cell of claim 1 wherein the bottom layer forms part of one of the first or second parallel conducting lines.

14. The vertical thyristor memory cell of claim 1 further comprising:
pluralities of first and second parallel isolation trenches, the first parallel isolation trenches lines in the first direction and the second parallel conducing lines in the second direction perpendicular to the first direction, the first and second parallel isolation trenches completely enclosing the top, first intermediate and second intermediate layers and at least partially enclosing the bottom layer of the vertical thyristor memory cells.

15. The vertical thyristor memory cell of claim 14 wherein the first parallel conducting lines are connected to the top layers of the vertical thyristor memory cells, and the bottom layers of the vertical thyristor memory cells form parts of the second parallel conducting lines, the second parallel isolation trenches completely enclosing the bottom layers in a first direction.

16. The vertical thyristor memory cell of claim 15 wherein the first parallel isolation trenches further comprise metal bridges disposed near the bottom of the first parallel isolation trenches between two neighboring vertical thyristor memory cells in the second direction, the metal bridges electrically connecting the bottom layers of the two vertical thyristor memory cells.

17. The vertical thyristor memory cell of claim 16 wherein the metal bridges comprise tungsten.

18. The integrated circuit memory array of claim 16 further comprising N+ regions below the metal bridges and extending to the bottom layers of two neighboring vertical thyristor memory cells in the second direction.

19. The vertical thyristor memory cell of claim 14 further comprising:
at least one assist gate electrode disposed in one of the parallel isolation trenches, the at least one assist gate electrode located over and spanning the first intermediate layer between the top layer and the second intermediate layer to form an MOS transistor to speed the operation of the vertical thyristor memory cell.

20. The vertical thyristor memory cell of claim 19 wherein the at least one assist gate electrode is disposed in one of the first parallel isolation trenches.

21. The vertical thyristor memory cell of claim 14 further comprising:
at least one assist gate electrode in one of the parallel isolation trenches, the at least one assist gate electrode located over and spanning the second intermediate layer between the first intermediate layer and the bottom layer to form an MOS transistor to speed the operation of the vertical thyristor memory cell.

22. The vertical thyristor memory cell of claim 21 wherein the at least one assist gate electrode is disposed in one of the first parallel isolation trenches.

23. A method of manufacturing vertical thyristor memory cells in an integrated circuit array, the method comprising:
defining a plurality of first isolation trenches in a surface of a silicon substrate of first conductivity type, the first isolation trenches lines in a first direction;
filling the plurality of first isolation trenches with an insulating material;
defining a plurality of second isolation trenches over the surface of the silicon substrate in a second direction perpendicular to the first direction;
filling the plurality of second isolation trenches with an insulating material;
etching apertures in the surface of the silicon substrate, each aperture between a pair of first isolation trenches and a pair of second isolation trenches to create a bottom at a predetermined depth in the silicon substrate;
implanting dopants of second conductivity type to create a bottom layer of the second conductivity type at the bottom of the aperture;
growing a SiGe layer of first conductivity type in the aperture over the bottom layer of second conductivity;
growing a SiGe layer of second conductivity type in the aperture over the SiGe layer of first conductivity type;
growing a top layer of a first conductivity type in the aperture over the SiGe layer of second conductivity type;
wherein the bottom layer of second conductivity type, the SiGe layer of first conductivity type, the SiGe layer of second conductivity type and the top layer of first conductivity type form a thyristor stacked vertically in the silicon substrate surface.

24. The method of claim 23 wherein in the step of growing the SiGe layer of first and second conductivities, the amount of Ge is kept constant.

25. The method of claim 23 wherein in the step of growing the SiGe layer of first and second conductivities, the amount of Ge is varied.

26. The method of claim 25 wherein the amount of Ge is in the range of 2-30% mole fraction.

27. The method of claim 26 wherein in the step of growing the SiGe layers of first and second conductivities, the amount of Ge increases toward a junction between the SiGe layers of first and second conductivities.

28. The method of claim 26 wherein in the step of growing the SiGe layers of first and second conductivities, the amount of Ge decreases toward a junction between the SiGe layers of first and second conductivities.

29. The method of claim 23 further comprising:
before the step of growing a SiGe layer of second conductivity type, growing a SiGe layer of intrinsic conductivity in the aperture over the SiGe layer of first conductivity type.

30. The method of claim 23 further comprising:
depositing metal bridges in the plurality of first isolation trenches between aperture locations of two neighboring vertical thyristor memory cells in the second direction, each metal bridge located near the bottoms of the isolation trenches so as to electrically connect the bottom layer of second conductivity of the two neighboring vertical thyristor memory cells in the second direction.

31. The method of claim 30 wherein the metal bridges depositing step comprises depositing tungsten.

32. The method of claim 30 further comprising:
before the step of depositing metal bridges, implanting dopants of the second conductivity type in the plurality of first isolation trenches between aperture locations of two neighboring vertical thyristor memory cells in the second direction, to form an electrical link for bottom layers of the two neighboring vertical thyristor memory cells in the second direction.
